(19) United States
(12) Patent Application Publication
(10) Pub. No.: US 2006/0079075 A1
(43) Pub. Date: Apr. 13, 2006

(54) Gate structures with silicide sidewall barriers and methods of manufacturing the same

(76) Inventors: Chang-Won Lee, Gyeonggi-do (KR); Sun-Pil Youn, Seoul (KR); Gil-Heyun Choi, Gyeonggi-do (KR); Byung-Hak Lee, Gyeonggi-do (KR); Hee-Sook Park, Seoul (KR); Dong-Chan Lim, Seoul (KR); Jong-Ryeol Yoo, Gyeonggi-do (KR); Woong-Hee Sohn, Gyeonggi-do (KR)

Correspondence Address: MYERS BIGEL SIBLEY & SAJOVEC, PO BOX 37428, RALEIGH, NC, 27627, US

(21) Appl. No.: 11/201,736

(22) Filed: Aug. 11, 2005

(30) Foreign Application Priority Data
Aug. 12, 2004 (KR) 10-2004-0063555
Dec. 15, 2004 (KR) 10-2004-0106432

(51) Int. Cl. H01L 21/3205

(52) U.S. Cl. 438/587

(57) ABSTRACT

A gate structure includes a gate insulation layer on a substrate, a polysilicon layer pattern on the gate insulation layer, a composite metal layer pattern on the polysilicon layer pattern, and a metal silicide layer pattern on a sidewall of the composite metal layer pattern.

### CROSS REFERENCE TO RELATED APPLICATION

This application claims priority under 35 USC §119 to Korean Patent Application Nos. 2004-63555, filed on Aug. 12, 2004, and 2004-106432, filed on Dec. 15, 2004, the content of both of which is hereby incorporated by reference in its entirety.

### BACKGROUND OF THE INVENTION

The present invention relates to semiconductor devices and methods of manufacturing the same and, more particularly, to gate structures and methods of manufacturing the same.

Integrated semiconductor devices having increased packing density, increased operation frequency and low operation voltage have been developed. Sizes of patterns and spacing between patterns on chips have been reduced.

In some conventional semiconductor devices, polysilicon has been used for unit features, such as gate electrodes and electrical connections between devices. However, as pattern size has been reduced with increased integration of semiconductor devices, connection resistance has become an important issue. Because polysilicon has a relatively high resistance, a polysilicon electrical connection between patterns having small sizes may have a time constant (RC) and a resistance (R) relatively higher than those of a polysilicon electrical connection between patterns having large sizes.

Therefore, polysilicon/metal silicide having a resistance lower than that of polysilicon and other characteristics substantially similar to polysilicon has been widely used in semiconductor devices. For example, a multi-layered structure of a semiconductor device may include a polysilicon layer doped with impurities and a heat-resistant metal silicide layer including titanium silicide or tungsten silicide formed on the polysilicon layer. Such a multi-layered structure has been used in gate electrodes and electrical connections between the devices in very-large scale integrated (VLSI) circuits.

However, as tungsten silicide has a relatively high resistance of about 100 μΩ-cm, it is desirable to further reduce gate electrode resistance for ultra-large scale integrated (ULSI) circuits having a critical dimension of no more than about 0.25 μm. Accordingly, a gate structure including a tungsten layer and a polysilicon layer, which has a low resistance of about 10 μΩ-cm lower than that of a gate structure including only a polysilicon layer or a polysilicon layer and a silicide layer, has been proposed. Methods of manufacturing a gate structure having a low resistance are disclosed in U.S. Pat. No. 5,545,578, and Korean Patent Laid Open Publication Nos. 2004-001868 and 2003-058270.

FIG. 1 is a cross sectional view illustrating a conventional gate structure that includes a tungsten layer and a polysilicon layer. Referring to FIG. 1, a gate structure includes a gate oxide layer pattern 12 formed on a silicon substrate 10. A polysilicon layer pattern 14 doped with impurities is formed on the gate oxide layer pattern 12. A tungsten silicide layer pattern 16 is formed on the polysilicon layer pattern 14. A tungsten nitride layer pattern 18 is formed on the tungsten silicide layer pattern 16. A tungsten layer pattern 20 is formed on the tungsten nitride layer pattern 18. A hard mask layer pattern 22 is then formed on the tungsten layer pattern 20.

To cure damage to the gate insulating layer pattern 12 and the silicon substrate 10 generated in the etching processes, a re-oxidation process may be performed on the gate structure. The re-oxidation process typically selectively oxidizes the gate oxide layer pattern 12 and/or the silicon substrate 10 with little or no oxidation of tungsten in the tungsten silicide layer pattern 16, the tungsten nitride layer pattern 18 and the tungsten layer pattern 20.

Tungsten oxide is readily volatilized at a temperature of about 300° C. or higher, and has a plurality of pores. Therefore, although a tungsten oxide layer may be formed on a sidewall of the tungsten layer pattern 20 by the re-oxidation process, the sidewall of the tungsten layer pattern 20 generally is not protected from oxidants. As a result, the oxidants may concentrate at an interface between the tungsten layer pattern 20 and the polysilicon layer pattern 14, which can cause the gate structure to have an increased resistance. As mentioned above, an increase of the resistance in the gate structure may increase a RC time constant, which can bring about a read address strobe (RAS) to column address strobe (CAS) delay. This can reduce yield and/or operation speed. Also, because the gate oxide layer pattern 12 has a relatively low dielectric constant, a significant leakage current through the substrate 10 may be generated.

### SUMMARY OF THE INVENTION

In some embodiments of the present invention, a gate structure includes a gate insulation layer on a substrate, a polysilicon layer pattern on the gate insulation layer, a composite metal layer pattern on the polysilicon layer pattern, and a metal silicide layer pattern on a sidewall of the composite metal layer pattern. The composite metal layer pattern may include a metal nitride layer pattern on the polysilicon layer pattern and a metal layer pattern on the metal nitride layer pattern.

The gate insulation layer may include a material having a dielectric constant greater than that of silicon dioxide, for example, hafnium oxide (HfO2), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅) and/or calcium oxide (CaO). In some embodiments, the composite metal layer is narrower than the polysilicon layer pattern. In other embodiments, the composite metal layer pattern and the polysilicon layer pattern have substantially the same width. The gate structure may further include a second metal silicide layer pattern interposed between the composite metal layer pattern and the polysilicon layer pattern. The gate structure may also include a passivation layer disposed on sidewalls of the polysilicon layer pattern and the metal silicide layer pattern.

In additional embodiments of the present invention, a gate structure includes a gate insulation layer on a substrate, a polysilicon layer pattern on the gate insulation layer, and a composite metal layer pattern on a central portion of the polysilicon layer pattern and having a width less than that of the polysilicon layer pattern. A metal silicide layer pattern is disposed on a sidewall of the composite metal layer pattern, and a passivation layer is disposed on sidewalls of the polysilicon layer pattern and the metal silicide layer pattern.

In some embodiments of the present invention, methods of fabricating gate structures are provided. A gate insulation layer is formed on a substrate. A polysilicon layer, a composite metal layer and a capping layer pattern are formed on the gate insulation layer. The composite metal layer is etched using the capping layer pattern as an etching mask to form a composite metal layer pattern. A metal silicide layer pattern is formed on a sidewall of the composite metal layer pattern. The polysilicon layer is etched using the capping layer pattern as an etching mask to form a polysilicon layer pattern underlying the composite metal layer pattern. The metal silicide layer pattern may be formed by forming a sacrificial polysilicon layer on the substrate, the composite metal layer pattern and the capping layer pattern, and thermally treating the sacrificial polysilicon layer to form the metal silicide layer pattern on the sidewall of the composite metal layer pattern. The polysilicon layer pattern and the metal silicide layer may be oxidized to form a passivation layer. In further embodiments, a second metal silicide layer pattern is formed between the composite metal layer pattern and the polysilicon layer pattern.

In additional methods embodiments, a gate insulation layer is formed on a substrate, and a polysilicon layer, a composite metal layer, and a capping layer pattern are formed on the gate insulation layer. The composite metal layer is etched using the capping layer pattern as an etching mask to form a composite metal layer pattern, the composite metal layer pattern having a width less than that of the capping layer pattern. A sacrificial polysilicon layer is formed on the substrate, the composite metal layer pattern and the capping layer pattern. The sacrificial polysilicon layer is thermally treated to form a metal silicide layer pattern on the sidewall of the composite metal layer pattern. A remaining portion of the sacrificial polysilicon layer is removed, and the polysilicon layer is etched using the capping layer pattern as an etching mask to form a polysilicon layer pattern. The polysilicon layer pattern and the metal silicide layer are oxidized to form a passivation layer.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross sectional view illustrating a conventional gate structure;

FIG. 2 is a cross sectional view illustrating a gate structure in accordance with some embodiments of the present invention;

FIGS. 3 to 9 are cross sectional views illustrating operations for manufacturing the gate structure in FIG. 2 according to further embodiments of the present invention; and

FIGS. 10 to 17 are cross sectional views illustrating operations for manufacturing a transistor including the gate structure in FIG. 2 in accordance with additional embodiments of the present invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

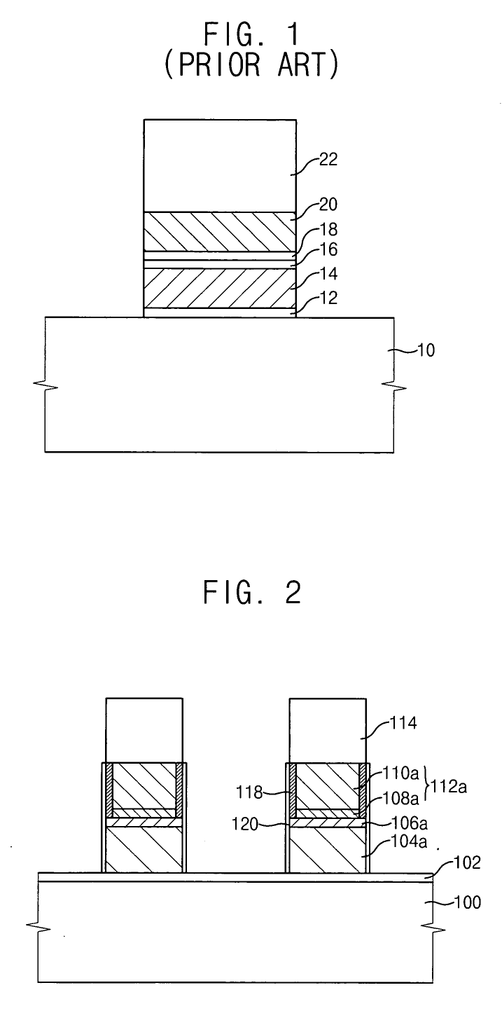

FIG. 2 is a cross sectional view illustrating a gate structure in accordance with some embodiments of the present invention. A semiconductor substrate 100 has an active region and a field region defined thereon. A gate insulation layer 102 is formed on the semiconductor substrate 100. A gate structure is formed on the gate insulation layer 102. The gate insulation layer 102 electrically insulates the gate structure 120 from the semiconductor substrate 100.

The gate structure includes the gate insulation layer 102, a polysilicon layer pattern 104a formed on the gate insulation layer 102, a first tungsten (or other metal) silicide layer pattern 106a, and a composite tungsten (or other metal) layer pattern 112a formed on the first tungsten silicide layer pattern 106a. The gate structure further includes a second tungsten (or other metal) silicide layer pattern 118 formed on a sidewall of the composite tungsten layer pattern 112a. The second tungsten silicide layer 118 is oxidized in a re-oxidation process to form a passivation layer 120 on sidewalls of the first and second tungsten silicide layer patterns 106a and 118, and the polysilicon layer pattern 104a.

The gate insulation layer 102 includes a material having a dielectric constant higher than that of silicon dioxide. For example, the gate insulation layer 102 may include a metal oxide. Examples of metal oxides that can be used for the gate insulation layer 102 include, but are not limited to, hafnium oxide (HfO₂), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum (tin) oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅), and calcium oxide (CaO). These can be used alone or in combination. The gate insulation layer 102 may also be formed by any of a number of different processes, including, but not limited to, sputtering, chemical vapor deposition (CVD) and atomic layer deposition (ALD).

A capping layer pattern 114 including silicon nitride is formed on the composite tungsten layer pattern 112a. The capping layer pattern 114 may reduce or prevent oxidation of the composite tungsten layer pattern 112a in a successive annealing process, and may serve as a hard mask layer for forming the gate structure. The first tungsten silicide layer pattern 106a may suppress formation of an insulation layer, such as a silicon nitride layer, that has a high resistance. The first tungsten silicide layer pattern 106a may have a thickness of about 80 Å to about 150 Å and, in some embodiments, about 110 Å.

The first tungsten silicide layer pattern 106a may prevent or reduce oxidant diffusion into an interface between the composite tungsten layer pattern 112a and the polysilicon layer pattern 104a in a re-oxidation process for curing damage to the gate insulation layer 102 and the semiconductor substrate 100 caused by an etching process. Thus, the first tungsten silicide layer pattern 106a may inhibit formation of an insulation layer, such as a silicon oxynitride layer formed by the reaction of nitrogen in a lower layer of the composite tungsten layer pattern 112a, silicon atoms in the polysilicon layer pattern 104a and diffused oxidants. The composite tungsten layer pattern 112a includes a tungsten nitride layer pattern 108a and a tungsten layer pattern 110a formed on the tungsten nitride layer pattern 108a. The tungsten nitride layer pattern 108a may have a thickness of about 30 Å to about 90 Å. The tungsten nitride layer pattern 108a may prevent a reaction between the polysilicon layer pattern 104a and the tungsten layer pattern 110a. The tungsten nitride layer pattern 108a and the tungsten layer pattern 110a may be formed by a variety of processes, including, but not limited to, sputtering, CVD, and ALD.

In some embodiments, the composite tungsten layer pattern 112a is formed on a central portion of the polysilicon layer pattern 104a, leaving exposed a peripheral portion of the polysilicon layer pattern 104a. Also, the composite tungsten layer pattern 112a may have a width less than that of the polysilicon layer pattern 104a so that a step is formed between the composite tungsten layer pattern 112a and the capping layer pattern 114. Alternatively, the composite tungsten layer pattern 112a may have a width substantially identical to that of the capping layer pattern 114 and/or the polysilicon layer pattern 104a.

The second tungsten silicide layer pattern 118 is formed on a sidewall of the composite tungsten layer pattern 112a, and the passivation layer 120 is formed on the first tungsten silicide layer pattern 118 in a re-oxidation process. The second tungsten silicide layer pattern 118 and the passivation layer 120 may prevent oxidants that penetrate into the composite tungsten layer pattern 112a from being concentrated at an interface of the polysilicon layer pattern 104a.

In some embodiments, in forming the first tungsten silicide layer pattern 118, a sacrificial polysilicon layer (not shown) having a thickness of about 80 Å to about 150 Å is formed on a structure including the composite tungsten layer pattern 112a. The semiconductor substrate 100 having the sacrificial polysilicon layer thereon is thermally treated to convert a portion of the sacrificial polysilicon layer that makes contact with the sidewall of the composite tungsten layer pattern 112a into a tungsten silicide layer. A portion of the sacrificial polysilicon layer that is not converted into the tungsten silicide layer is isotropically etched, leaving the second tungsten silicide layer pattern 118. If the second tungsten silicide layer pattern 118 were not present, oxidants might concentrate at an interface of the polysilicon layer pattern 112a so that a gate structure without the second tungsten silicide layer pattern 118 may have an increased resistance. The concentration of the oxidants may increase the resistance of such a gate structure. Although a gate structure without the second tungsten silicide layer pattern 118 may be re-oxidized to form a tungsten oxide layer on the sidewall of the composite tungsten layer pattern 112a, the oxidants may concentrate at the interface of the polysilicon layer pattern 112a, because the tungsten oxide layer may be easily volatilized at a temperature of about 300° C. or higher.

In contrast, in a gate structure of some embodiments of the present invention, the passivation layer 120 is formed from the second tungsten silicide layer pattern 118 by a re-oxidation process. Therefore, penetration of oxidants into the composite tungsten layer pattern 112a may be reduced or prevented. Also, because the gate insulation layer 102 includes a material having a dielectric constant higher than that of silicon oxide, a leakage current through the semiconductor substrate 100 may be reduced. As a result, the gate structure illustrated in FIG. 2 may have improved leakage current characteristics.

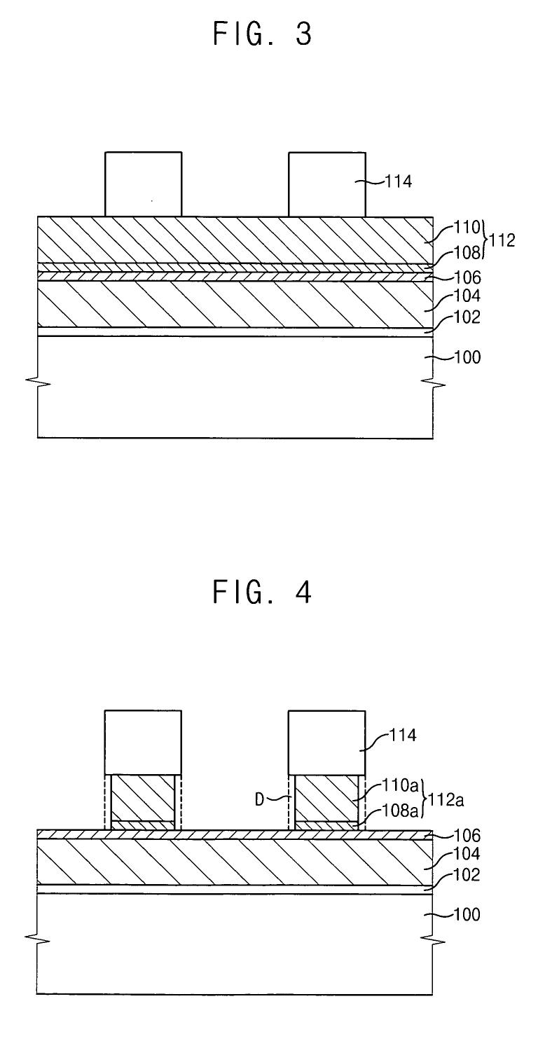

FIGS. 3 through 9 are cross sectional views illustrating operations for manufacturing the gate structure of FIG. 2 according to further embodiments of the present invention. Referring to FIG. 3, the gate insulation layer 102, a polysilicon layer 104, a first tungsten silicide layer 106, a composite tungsten layer 112 and the capping layer pattern 114 are sequentially formed on the semiconductor substrate 100. The gate insulation layer 102, for example, a silicon oxide or silicon oxynitride layer, may be formed on the semiconductor substrate 100 by a thermal oxidation process. The gate insulation layer 102 may include a material having a dielectric constant higher than that of silicon oxide. The gate insulation layer 102 may be formed by, for example, sputtering, CVD, or ALD process.

For example, to form an aluminum oxide layer by an ALD process, the semiconductor substrate 100 may be loaded into a chamber. A temperature and a pressure of the chamber may be appropriately controlled. If the temperature of the chamber is too low, reaction materials may have a poor reactivity, while, if the temperature of the chamber is too high, the reaction materials may rapidly crystallize so that a crystallized layer may have characteristics substantially identical or similar to those formed by a CVD process. In some embodiments, the chamber has a temperature of about 150° C. to about 400° C., and in further embodiments, about 300° C. A layer formed at a temperature of about 300° C. may have good characteristics, substantially identical or similar to those formed by an ALD process.

An aluminum source is introduced in the chamber as a first reaction material for a time interval of, for example, about two seconds. An example of a suitable aluminum source is trimethylaluminum [TMA:Al(CH₃)₃]. A first portion of the aluminum source may be chemisorbed on the semiconductor substrate 100 and a second portion of the aluminum source may be physisorbed on the semiconductor substrate 100. In particular, the first portion of the aluminum source may be chemisorbed on the silicon nitride layer. A first argon purge gas is introduced into the chamber for a time interval of about, for example, three seconds to remove the second portion of the aluminum source physisorbed on the semiconductor substrate 100.

An oxidant is introduced into the chamber for a time interval of, for example, about three seconds. Examples of appropriate oxidants include O₃, H₂O, H₂O₂, CH₃OH, and C₂H₅OH. These can be used alone or in combination. As a result, the first portion of the aluminum source is oxidized to form a solid material including aluminum oxide on the semiconductor substrate 100. A second argon gas is then introduced into the chamber for a time interval of, for example, about three seconds to remove remaining oxidant in the chamber.

The operations of introducing the aluminum source, introducing the first argon gas, introducing the oxidant and introducing the second argon gas are repeatedly carried out to form the gate insulation layer 102 having a desired thickness and including aluminum oxide. The gate insulation layer 102 including aluminum oxide may suppress a leakage current in the gate structure so that the gate insulation layer 102 may be relatively thin.

The polysilicon layer 104 having a thickness of about 300 Å to about 1,500 Åmay be formed on the gate insulation layer 102 by a CVD process. The first tungsten silicide layer 106 having a thickness of about 30 Å to about 70 Å is formed on the polysilicon layer 104. In particular, a tungsten layer having a thickness of about 30 Å to about 60 Å is formed on the polysilicon layer 104. The tungsten layer is thermally treated at a temperature of about 600° C. under a nitrogen atmosphere to form the first tungsten silicide layer 106.

The composite tungsten layer 112 includes a tungsten nitride layer 108 and a tungsten layer 110 formed on the tungsten nitride layer 108. The tungsten nitride layer 108 having a thickness of about 30 Å to about 100 Å may be formed by a CVD process. The tungsten layer 110 having a thickness of about 200 Å to about 800 Å may be formed by a sputtering process that is carried out at a temperature of about 150° C. under a pressure of about 4 mTorr at a power of about 2 kW. The composite tungsten layer 112 may be formed in-situ in a single chamber.

The capping layer pattern 114 including nitride is formed on the tungsten layer 110. In particular, a silicon nitride layer having a thickness of about 1,500 Å to about 2,500 Å, which may prevent oxidation of the tungsten layer 110 in a following annealing process, is formed on the tungsten layer 110. The silicon nitride layer is etched by a photolithography process to form the capping layer pattern 114.

Referring to FIG. 4, the composite tungsten layer 112 is over-etched by, for example, a wet etching process or an isotropic etching process using the capping layer pattern 114 as an etching mask to form the composite tungsten layer pattern 112a having a width less than that of the capping layer pattern 114. As a result, a space D defined by a bottom face of the capping layer pattern 114 and a sidewall of the composite tungsten layer pattern 112a is formed. The semiconductor substrate 100 including the composite tungsten layer pattern 112a is cleaned to remove residue from the etching process.

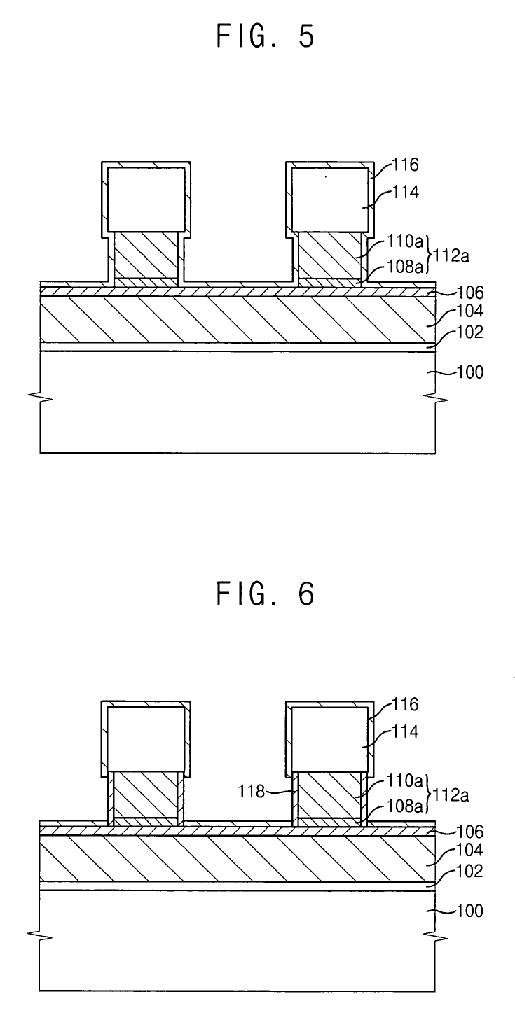

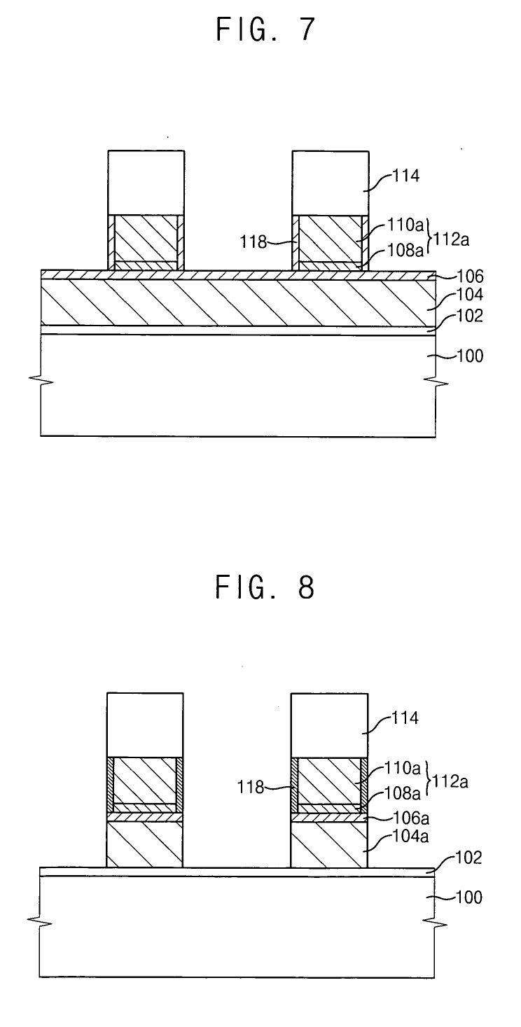

Referring to FIG. 5, a sacrificial polysilicon layer 116 having a thickness of about 100 Å is formed on the semiconductor substrate 100, the sidewall of the composite tungsten layer pattern 112a and the capping layer pattern 114. Referring to FIG. 6, the sacrificial polysilicon layer 116 is thermally treated in a nitrogen atmosphere to convert a portion of the sacrificial polysilicon layer 116 on the sidewall of the composite tungsten layer pattern 112a into the second tungsten silicide layer pattern 118. The thermal treatment process may be performed at least once at a temperature of about 600° C. to about 1,200° C. in an atmosphere including nitrogen gas and an inert gas. Referring to FIG. 7, a portion of the sacrificial polysilicon layer 116 not converted into the second tungsten silicide layer pattern 118 may be removed by an isotropic etching process.

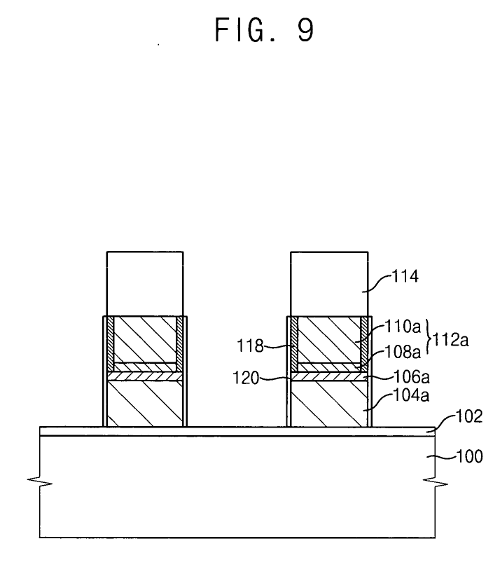

Referring to FIG. 8, the first tungsten silicide layer 106 and the polysilicon layer 104 are etched using the capping layer pattern 114, the composite tungsten layer pattern 112a and the first tungsten silicide layer pattern 118 as an etching mask to form the first tungsten silicide layer pattern 106a and the polysilicon layer pattern 104a. Referring to FIG. 9, to cure damage to the semiconductor substrate 100 and the gate insulation layer 102 caused by the etching process and thereby improve gate oxide integrity, the polysilicon layer pattern 104a, the first tungsten silicide layer pattern 106a and the second tungsten silicide layer pattern 118 are oxidized by a re-oxidation process to form the passivation layer 120 on the sidewalls of the first tungsten silicide layer pattern 106a, the second tungsten silicide layer pattern 118 and the polysilicon layer pattern 104a. The re-oxidation process may be performed at a temperature of about 600° C. to about 1,000° C. in an atmosphere including a vapor gas and hydrogen gas.

In the illustrated embodiments, the re-oxidation process may cure damage to the semiconductor substrate 100 and the gate insulation layer 102 generated in etching the semiconductor substrate 100 and the gate insulation layer 102, and may thereby improve gate oxide integrity (GOI). Also, the passivation layer 120 may prevent oxidants from penetrating into a side face of the gate structure so that the gate structure may have a relatively low resistance.

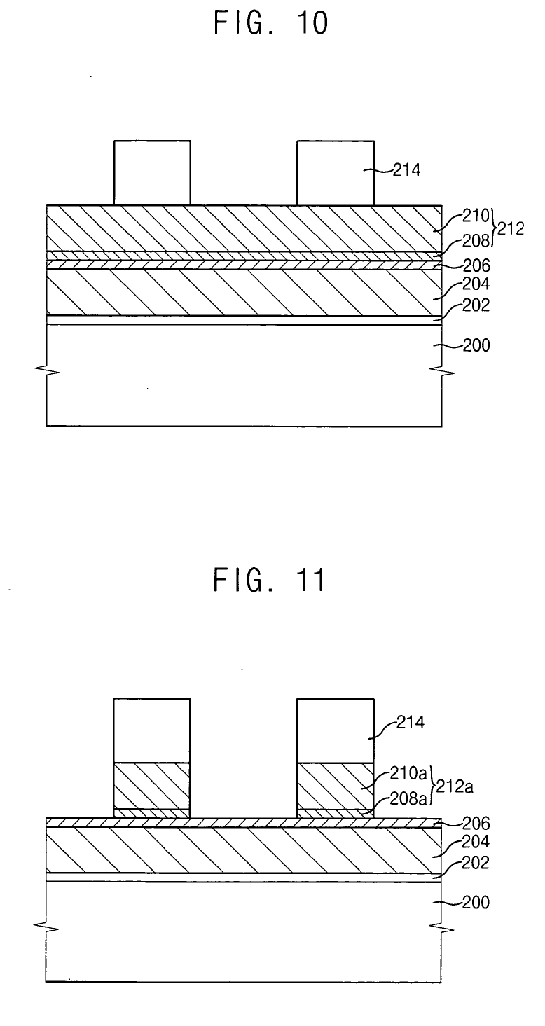

FIGS. 10 through 17 are cross sectional views illustrating operations for manufacturing a transistor including the gate structure in FIG. 2 in accordance with further embodiments of the present invention. Referring to FIG. 10, a gate insulation layer 202, a polysilicon layer 204, a first tungsten silicide layer 206, a composite tungsten layer 212 and a capping layer pattern 214 are sequentially formed on the semiconductor substrate 200. The gate insulation layer 202 may include a material having a dielectric constant higher than that of silicon oxide. The gate insulation layer 202 may be formed using a process substantially identical to that described above with reference to FIG. 3.

Referring to FIG. 11, the composite tungsten layer 212 is dry-etched using the capping layer pattern 214 as an etching mask to form a composite tungsten layer pattern 212a having a width substantially identical to that of the capping layer pattern 214. The semiconductor substrate 200 including the composite tungsten layer pattern 212a is cleaned to remove residue from the etching process.

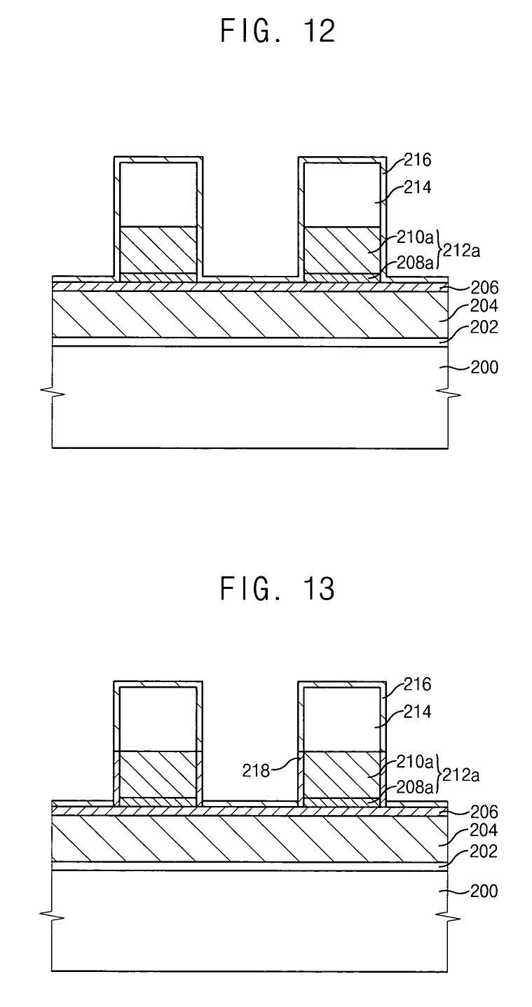

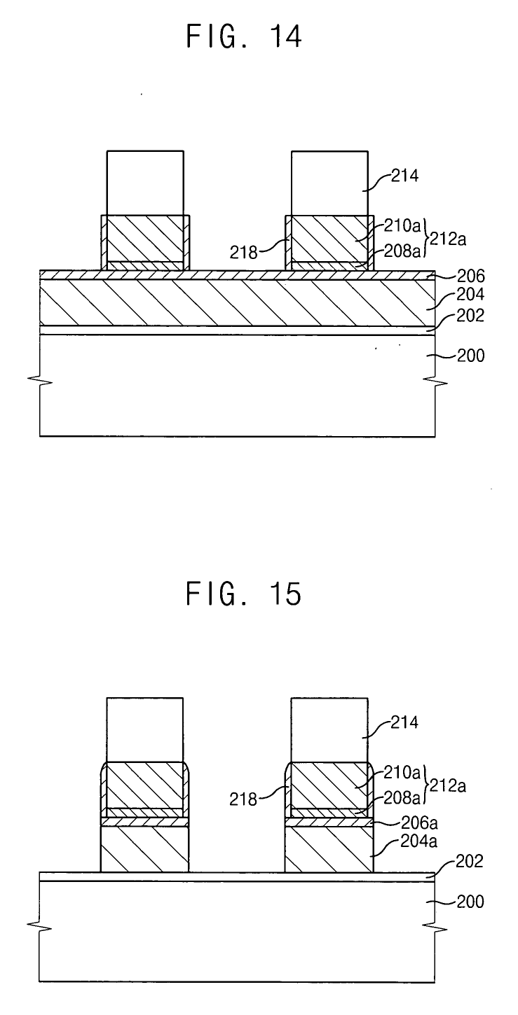

Referring to FIG. 12, a sacrificial polysilicon layer 216 having a thickness of about 100 Å is formed on the semiconductor substrate 200, the sidewall of the composite tungsten layer pattern 212a and the capping layer pattern 214. Referring to FIG. 13, the sacrificial polysilicon layer 216 is thermally treated in an atmosphere including a nitrogen gas and a hydrogen gas to form a second tungsten silicide layer pattern 218 on the sidewall of the composite tungsten layer pattern 212a. The thermal treatment process may be carried out at least once at a temperature of about 600° C. to about 1,200° C. in an atmosphere including nitrogen gas and an inert gas. Referring to FIG. 14, a portion of the sacrificial polysilicon layer 216 not converted into the second tungsten silicide layer pattern 218 may be removed by an isotropic etching process.

Referring to FIG. 15, the first tungsten silicide layer 206 and the polysilicon layer 204 are etched using the capping layer pattern 214, the composite tungsten layer pattern 212a and the second tungsten silicide layer pattern 218 as an etching mask to form the first tungsten silicide layer pattern 206a and the polysilicon layer pattern 204a. Referring to FIG. 16, to cure damage to the semiconductor substrate 200 and the gate insulation layer 202 caused by the etching process and thereby improve gate oxide integrity, the polysilicon layer pattern 204a, the second tungsten silicide layer pattern 206a and the first tungsten silicide layer pattern 218 are oxidized by a re-oxidation process to form a passivation layer 220 on the sidewalls of the second tungsten silicide layer pattern 218, the first tungsten silicide layer pattern 206a and the polysilicon layer pattern 204a.

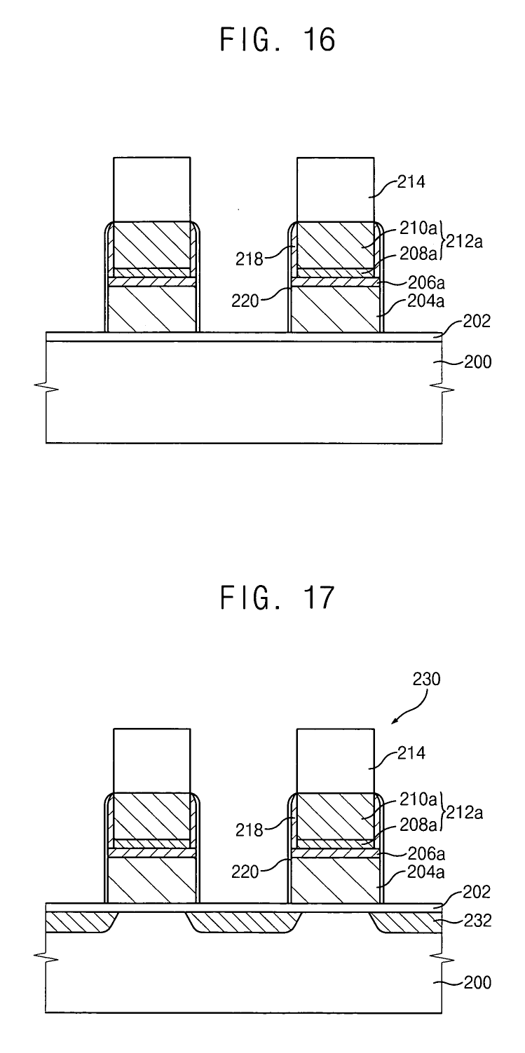

The re-oxidation process may cure damage to the semiconductor substrate 200 and the gate insulation layer 202 generated in etching the semiconductor substrate 200 and the gate insulation layer 202, thereby improving a gate-oxide integrity (GOI). Also, the passivation layer 220 may prevent oxidant from penetrating into a side face of the gate structure so that the gate structure may have a relatively low resistance. Referring to FIG. 17, impurities may be implanted or otherwise doped into the semiconductor substrate 200 using the gate structure 230 as an ion implantation mask to form source/drain regions 232.

According to various embodiments of the present invention, because a tungsten silicide layer pattern is formed on the sidewall of a gate structure, a passivation layer may be formed on the gate structure by a re-oxidation process. The passivation layer may prevent oxidant from penetrating into the gate structure so that an oxide layer may not be formed on the sidewall of the gate structure, which may thereby reduce a resistance of the gate structure. Because the gate structure may have a low resistance, a semiconductor device having the gate structure may have improved RC characteristics and operation speed. Furthermore, because the gate insulation layer may include a material having a dielectric constant higher than that of silicon oxide, the semiconductor device may have improved leakage current characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A gate structure comprising:
a gate insulation layer on a substrate;
a polysilicon layer pattern on the gate insulation layer;
a composite metal layer pattern on the polysilicon layer pattern; and
a metal silicide layer pattern on a sidewall of the composite metal layer pattern.

2. The gate structure of claim 1, wherein the gate insulation layer comprises a material having a dielectric constant greater than that of silicon dioxide.

3. The gate structure of claim 2, wherein the material of the gate insulation layer comprises hafnium oxide (HfO2), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅) and/or calcium oxide (CaO).

4. The gate structure of claim 1, wherein the composite metal layer pattern comprises:
a metal nitride layer pattern on the polysilicon layer pattern; and
a metal layer pattern on the metal nitride layer pattern.

5. The gate structure of claim 1, wherein the composite metal layer is narrower than the polysilicon layer pattern.

6. The gate structure of claim 1, wherein the composite metal layer pattern and the polysilicon layer pattern have substantially the same width.

7. The gate structure of claim 1, wherein the metal silicide layer comprises a first metal silicide layer, and further comprising a second metal silicide layer pattern interposed between the composite metal layer pattern and the polysilicon layer pattern.

8. The gate structure of claim 1, further comprising a passivation layer disposed on sidewalls of the polysilicon layer pattern and the metal silicide layer pattern.

9. A gate structure comprising:
a gate insulation layer on a substrate;
a polysilicon layer pattern on the gate insulation layer;
a composite metal layer pattern on a central portion of the polysilicon layer pattern and having a width less than that of the polysilicon layer pattern;
a metal silicide layer pattern disposed on a sidewall of the composite metal layer pattern; and
a passivation layer disposed on sidewalls of the polysilicon layer pattern and the metal silicide layer pattern.

10. The gate structure of claim 9, wherein the gate insulation layer comprises a material having a dielectric constant greater than that of silicon dioxide.

11. The gate structure of claim 10, wherein the material of the gate insulation layer comprises hafnium oxide (HfO₂), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅) and/or calcium oxide (CaO).

12. The gate structure of claim 9, wherein the composite metal layer pattern comprises:
a metal nitride layer pattern on the polysilicon layer pattern; and
a metal layer pattern on the metal nitride layer pattern.

13. The gate structure of claim 9, wherein the metal silicide layer pattern comprises a first metal silicide layer pattern, and further comprising a second metal silicide layer pattern interposed between the composite metal layer pattern and the polysilicon layer pattern.

14. A method of manufacturing a gate structure, comprising:
forming a gate insulation layer on a substrate;
forming a polysilicon layer, a composite metal layer and a capping layer pattern on the gate insulation layer;
etching the composite metal layer using the capping layer pattern as an etching mask to form a composite metal layer pattern;
forming a metal silicide layer pattern on a sidewall of the composite metal layer pattern; and
etching the polysilicon layer using the capping layer pattern as an etching mask to form a polysilicon layer pattern underlying the composite metal layer pattern.

15. The method of claim 14, wherein the gate insulation layer comprises a material having a dielectric constant greater than that of silicon dioxide.

16. The method of claim 15, wherein the material of the gate insulation layer comprises hafnium oxide (HfO₂), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅) and/or calcium oxide (CaO).

17. The method of claim 14, wherein forming the composite metal layer pattern comprises forming a metal nitride layer pattern on the polysilicon layer pattern and a metal layer pattern on the metal nitride layer pattern.

18. The method of claim 14, wherein the composite metal layer pattern has a width less than that of the polysilicon layer pattern and is formed on a central portion of the polysilicon layer pattern.

19. The method of claim 14, wherein the composite metal layer pattern has a width substantially equal to that of the polysilicon layer pattern.

20. The method of claim 14, wherein forming a metal silicide layer pattern comprises forming a first metal silicide layer pattern, and further comprising forming a second metal silicide layer pattern between the composite metal layer pattern and the polysilicon layer pattern.

21. The method of claim 14, wherein forming a metal silicide layer pattern comprises:
forming a sacrificial polysilicon layer on the substrate, the composite metal layer pattern and the capping layer pattern; and
thermally treating the sacrificial polysilicon layer to form the metal silicide layer pattern on the sidewall of the composite metal layer pattern.

22. The method of claim 21, wherein thermally treating comprises thermally treating at a temperature of about 600° C. to about 1,200° C. in a nitrogen atmosphere.

23. The method of claim 21, further comprising removing a remaining portion of the sacrificial polysilicon layer by a wet etching process.

24. The method of claim 14, further comprising oxidizing the polysilicon layer pattern and the metal silicide layer to form a passivation layer.

25. A method of manufacturing a gate structure, comprising:
forming a gate insulation layer on a substrate;
forming a polysilicon layer, a composite metal layer and a capping layer pattern on the gate insulation layer;
etching the composite metal layer using the capping layer pattern as an etching mask to form a composite metal layer pattern, the composite metal layer pattern having a width less than that of the capping layer pattern;
forming a sacrificial polysilicon layer on the substrate, the composite metal layer pattern and the capping layer pattern;
thermally treating the sacrificial polysilicon layer to form a metal silicide layer pattern on the sidewall of the composite metal layer pattern;
removing a remaining portion of the sacrificial polysilicon layer;
etching the polysilicon layer using the capping layer pattern as an etching mask to form a polysilicon layer pattern; and
oxidizing the polysilicon layer pattern and the metal silicide layer to form a passivation layer.

26. The method of claim 25, wherein the gate insulation layer comprises a material having a dielectric constant greater than that of silicon dioxide.

27. The method of claim 26, wherein the material of the gate insulation layer comprises hafnium oxide (HfO₂), zirconium oxide (ZrO₂), tantalum oxide (Ta₂O₅), yttrium oxide (Y₂O₃), niobium oxide (Nb₂O₅), aluminum oxide (Al₂O₃), titanium oxide (TiO₂), cerium oxide (CeO₂), indium oxide (In₂O₃), ruthenium oxide (RuO₂), strontium oxide (SrO), magnesium oxide (MgO), boron oxide (B₂O₃), stannum oxide (SnO₂), lead oxide (PbO), lead dioxide (PbO₂), triplumbum tetraoxide (Pb₃O₄), vanadium oxide (V₂O₃), lanthanum oxide (La₂O₃), praseodymium oxide (Pr₂O₃), diantimony trioxide (Sb₂O₃), diantimony pentaoxide (Sb₂O₅) and/or calcium oxide (CaO).

28. The method of claim 25, wherein etching the composite metal layer using the capping layer pattern as an etching mask to form a composite metal layer pattern comprises:
forming a metal nitride layer pattern on the polysilicon layer pattern; and
forming a metal layer pattern on the metal nitride layer pattern.

29. The method of claim 25, wherein the metal silicide layer comprises a first metal silicide layer, and further comprising forming a second metal silicide layer pattern between the composite metal layer pattern and the polysilicon layer pattern.
